(19) United States
(12) Patent Application Publication
(10) Pub. No.: US 2010/0051086 A1
(43) Pub. Date: Mar. 4, 2010

(54) REDUNDANT ARRAY OF SINGLE AXIS TRACKING SOLAR PANELS

(76) Inventors: Marvin S. Keshner, Sonora, CA (US); Erik Vaaler, Redwood City, CA (US)

Correspondence Address: WEISS & MOY PC, 4204 NORTH BROWN AVENUE, SCOTTSDALE, AZ, 85251, US

(21) Appl. No.: 12/199,309

(22) Filed: Aug. 27, 2008

(51) Int. Cl. F24J 2/38; H01L 31/052

(52) U.S. Cl. 136/246; 126/576

(57) ABSTRACT

An array of independent single-axis tracking solar panel assemblies is provided which, compared to prior-art “ganged” tracking assemblies, can reduce production, installation, and operation costs of solar panel arrays, reduce power loss and down-time in the event of single-point failure, and increase annual power production. Each independent single-axis tracking solar panel assembly has one or more solar panels mounted on a rotatable support structure and its own motor, its own motor controller, and its own reduction gear box. Each assembly is supported at two points, one in the north and one in the south, so that the one or more solar panels in an assembly are rotated from east to west to track the angle of the sun. Each independent assembly may be wired directly to a power inverter and all may be wired in parallel. Each is protected with a series diode so that if one shorts, it cannot shunt power from another. If one fails, the power from each of the others continues to the power inverter, unaffected. Each assembly may be oriented so that it has a fixed tilt in the range of 20-40 degrees.

### FIELD OF THE INVENTION

This invention relates generally to a solar energy collection system. More specifically, this invention relates to a solar collection array of single-axis tracking solar panel assemblies.

### BACKGROUND OF THE INVENTION

In general terms, a solar energy collection system includes an array of energy conversion modules, such as photovoltaic (PV) modules, also known as solar panels, arranged in the form of rows and mounted on a support structure. The solar panels are oriented to optimize the solar panel energy output to suit the particular solar energy collection system design requirements. A solar energy collection system can have a capacity from a few kilowatts to a hundred kilowatts or more, depending upon the number of solar panels used to form the array. The solar panels can be installed wherever there is exposure to the sun for significant portions of the day. For example, the solar panels may be installed on a solar farm, a facility where many photovoltaic (PV) modules are centrally located. The minimum size for a solar farm is about one (1) megawatt.

Conventionally, the solar panels may be mounted on a tracking support structure that aims the solar panels toward the sun as the sun moves across the sky during the day and as the sun path moves in the sky during the year. Tracking the sun can lead to a significant increase in annual radiation falling on the tracked surface, thus an increase in efficiency, compared to a fixed structure. Tracking the sun using such tracking solar panels increases the number of kilowatt hours of electricity that are generated per year and also improves the number of kilowatt hours that are available in the early morning (8 am-10 am standard time) and in the late afternoon (2 pm-5 pm standard time). The cost of a tracking support structure adds significantly to the overall cost of a solar collection system.

There are many designs for single-axis tracking solar panel arrays in which the solar panels are mounted at a zero degree fixed angle in the north to south direction and rotate from east to west to track the position of the sun in the east to west direction. Most of these designs use a long central tube that rotates many hundreds or thousands of panels simultaneously from east to west. As shown in FIG. 1, by mounting a large number of solar panels 2 on a single rotating tube 4 (a “long array”) supported by a plurality of bearings 5, the number of motors, motor controllers and gear boxes can be greatly reduced (identified collectively as 6). The controller 8 may be, for example, a manual winch mechanism with a single hand wheel to provide the drive to rotate the long central tube. Several designs go further and gang 10-100 of the long arrays through a set of rods and gears so that thousands to tens of thousands of solar panels can be rotated with a single motor, a single motor controller and a single reduction gear box.

Unfortunately, there are several disadvantages associated with such designs. As many solar panels are connected together in the north to south direction, they are prevented from also being tilted in the north-south direction forcing the north-south tilt to be zero degrees. This greatly reduces annual energy production at subtropical, temperate, and higher latitudes, where the daily path of the sun shifts significantly from north to south over the course of the year. Moreover, while these designs require fewer motors, controllers and gear boxes, these components and cross-section structural components have to be larger because of the heavier load they must move, and highly reliable because a failure in any one of these components creates a failure in the entire system. A single point of failure may render a large part of the system or the entire system inoperable. Large components with very low failure rates also tend to be very expensive, as these are likely to be somewhat customized devices made in low volumes; they often add more cost to a solar farm or other solar installation than the extra energy production from the tracking system is worth. The goal of large solar farms and other solar installations is the reliable production of power, with infrequent down time and minimal maintenance costs. With the vulnerability that results from single points of failure, this goal is difficult to achieve. For prior art arrays, a single failure can often result in 10% or larger power reductions. For the ganged designs, a single failure can result in the entire system becoming inoperable for many days.

Another major cost element involved in the establishment of a solar energy collection system is the cost of the tracking support structure used to mount the solar panels of the conventional array in proper position for receiving and converting solar energy. Such designs require relatively complex and, hence, costly positioning apparatus for maintaining the panels in proper alignment with the longitudinal axis of solar travel over the collector during each day, and throughout the year. Connecting many solar panels with a long central tube requires careful alignment of the solar panels.

In addition to the mechanical complexity of the support structure, costs are also affected by the number and size of the footings to which a tracking support structure is typically fastened. Footings or foundations, typically made of concrete or a similar material, provide a precise and stable reference plane. The position and angle of each solar panel must be adjusted relative to the concrete foundations during the installation process. The concrete foundations are expensive, as is the labor to individually align each solar panel to a common axis. When multiple rows of solar panels are then further ganged through a set of rods or gears to a single motor, additional alignment is required. Thus additional installation costs are incurred. The cost of installation is a major factor in the overall cost of an array of solar panels, often equal to the cost of the solar panels themselves.

Accordingly, there has been a need for a novel solar collection array of single-axis tracking solar panel assemblies of simplified construction, which can use relatively inexpensive motors, gear boxes and motor controllers, etc. There is an additional need for a solar collection array of single-axis tracking solar panel assemblies in which a single point of failure renders only a single assembly inoperable and, as the single affected assembly is small, only a small percentage of the solar installation power generating capacity is affected. There is a still further need for a solar collection array of single-axis tracking solar panel assemblies which minimize the cost of generating electricity from a tracking solar collection system at a price that is competitive with other forms of electricity generation. There is a need for a solar collection array of single-axis tracking solar panel assemblies in which the solar panels in each assembly may be tilted independently in the north-south direction to increase energy production. There is an additional need for a solar collection array of single-axis tracking solar panel assemblies that may be supported on an uneven surface to substantially avoid the use of concrete footings or foundations. There is a still further need for a solar collection array that reliably produces power with infrequent downtime and requiring minimal maintenance. The present invention fulfills these needs and provides other related advantages.

### SUMMARY OF THE INVENTION

The present invention resides in a solar collection array that provides reliable power generation using relatively inexpensive components without the need for concrete foundations, which nevertheless produces energy yields competitive with other solar collection systems. The array comprises, generally, a plurality of tracking solar panel assemblies each comprising at least one energy conversion module mounted on a rotating support structure and a drive mechanism for moving the at least one energy conversion module of the respective tracking solar panel assembly around a single axis, whereby each of the plurality of tracking solar panel assemblies operate independently from the other tracking solar panel assemblies within the solar collection array.

Other features and advantages of the present invention will become apparent from the following more detailed description, taken in conjunction with the accompanying drawings which illustrate, by way of example, the principles of the invention.

### BRIEF DESCRIPTION OF THE DRAWINGS

The accompanying drawings illustrate the invention. In such drawings:

FIG. 1 is a schematic view of a prior art single-axis tracking solar farm;

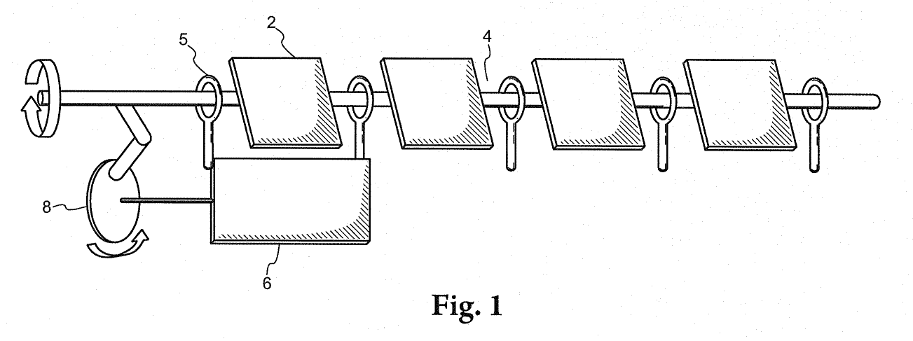

FIG. 2 is a schematic view of an exemplary array of independent single-axis tracking solar panel assemblies embodying the invention;

FIG. 3 is a schematic view of one of the independent single-axis tracking solar panel assemblies with a self-contained drive mechanism, wind sensor and protective diode, and illustrating the conceptual relationship between the tracking solar assembly and the RF module;

FIG. 4 is a schematic view similar to FIG. 2, illustrating another exemplary array with a redundant row of independent single-axis tracking solar panel assemblies;

FIG. 5 is a schematic view of a pair of independent single-axis tracking solar panel assemblies supported at one point in the north and one point in the south; and

FIG. 6 is an expanded view of the self-contained drive mechanism of FIG. 3 and wind sensor.

### DETAILED DESCRIPTION OF THE PREFERRED EMBODIMENTS

As shown in the drawings for purposes of illustration, the present invention is concerned with an improved solar collection array, generally designated in the accompanying drawings by the reference number 10. The solar collection array comprises, generally, a plurality of tracking solar panel assemblies 12 each comprising at least one energy conversion module 14 mounted on a rotating support structure 16 and a drive mechanism 18 for moving the at least one energy conversion module 14 of the respective tracking solar panel assembly 12 around a single axis, whereby each of the plurality of tracking solar panel assemblies 12 operate independently from the other tracking solar panel assemblies within the solar collection array 10.

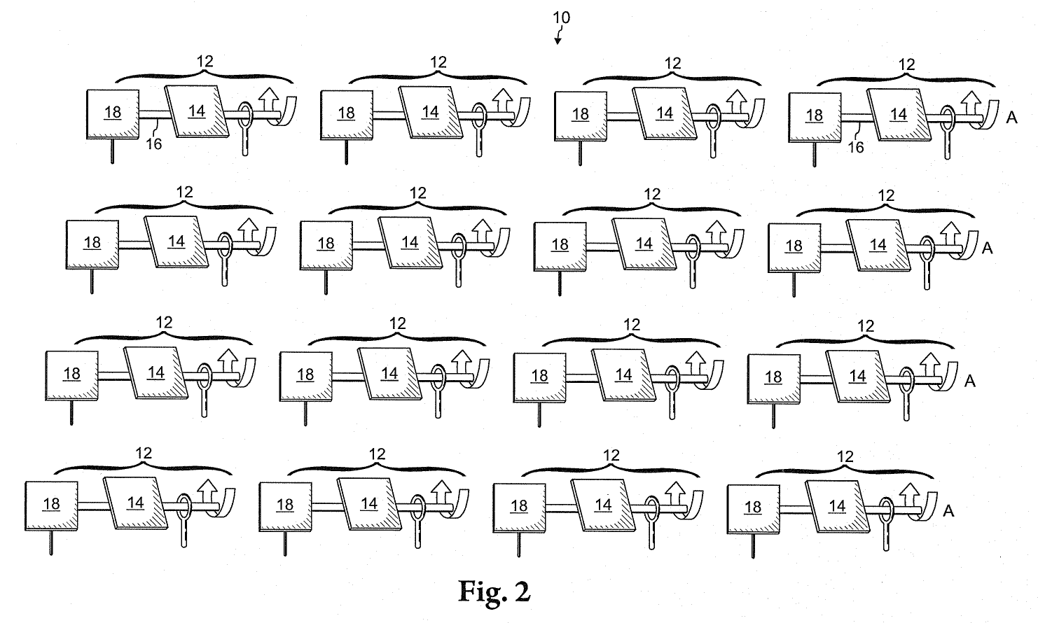

In accordance with the present invention, and as illustrated with respect to a preferred embodiment in FIGS. 2 through 6, each tracking solar panel assembly 12 has its own respective drive mechanism that moves the at least one associated energy conversion module around the single axis of the rotating support structure to track the actual position of the sun. A single point of failure only renders a single assembly inoperable and as the single affected assembly is small, only a small percentage of the solar installation power generating capacity is affected. The at least one energy conversion module in each assembly may be tilted independently in the north-south direction to increase energy production. Each independent assembly may be supported on an uneven surface to substantially avoid the use of concrete footings or foundations as hereinafter described.

As shown in FIG. 2, each tracking solar panel assembly 12 incorporates at least one flat, rectangular energy conversion module, e.g., a photovoltaic and/or thermovoltaic cell or a solar panel made using such cells, configured to convert solar energy into electrical energy. As used herein, energy conversion modules are referred to herein as solar panels. However, the use of alternative energy conversion modules does not depart from the spirit and scope of the present invention.

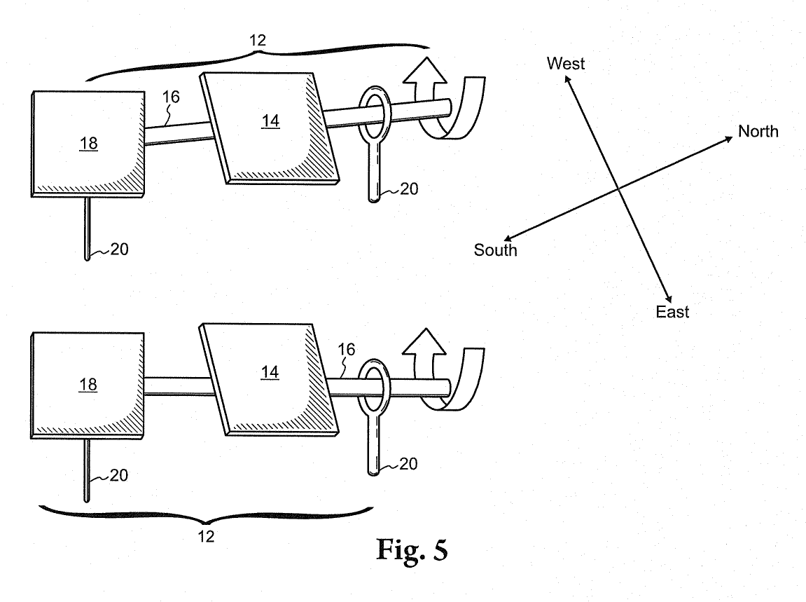

The rotating support structure 16 may be a torsion tube or the like. As shown in FIG. 5, the rotating support structure may be generally north-south oriented to define a north-south axis. Although a north-south orientation of the rotating support structure is shown, such orientation is not a limitation of the present invention. The rotating support structure may be supported at two spaced apart points by a pair of support bearings 20. In a preferred embodiment as shown in FIG. 5, the support bearings 20 have an upper ring portion to receive the rotating support structure and a lower pole-type portion adapted to be disposed in the ground or other surface. Although such support bearings 20 are shown, such configuration is not a limitation of the present invention.

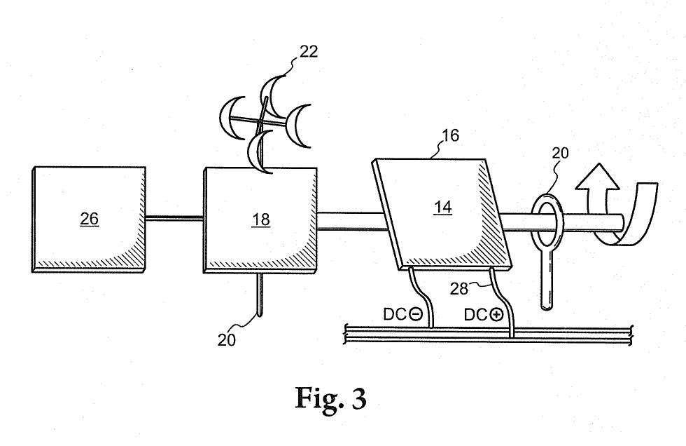

Each tracking solar panel assembly 12 may be supported at the two spaced apart points a and b (See FIG. 3) so that the assembly may be supported in uneven ground or on supports of uneven height. There is no need for concrete foundations or supports of even height. As each tracking solar panel assembly 12 is supported at two points and as any two points determine a line, the only effect of uneven ground would be to vary the exact north-south angle around which the at least one solar panel in an assembly is rotated. Small variations in the north-south angle have only minimal impact on the amount of energy produced. After placement, no additional labor is required to improve their alignment. This ground variation adaptability can save considerable cost. The support bearings are generally broad enough as contact points for most ground surfaces without the need for supports. However, as practiced, optional ballast blocks may be provided for use as supports in situations of particularly soft ground surfaces.

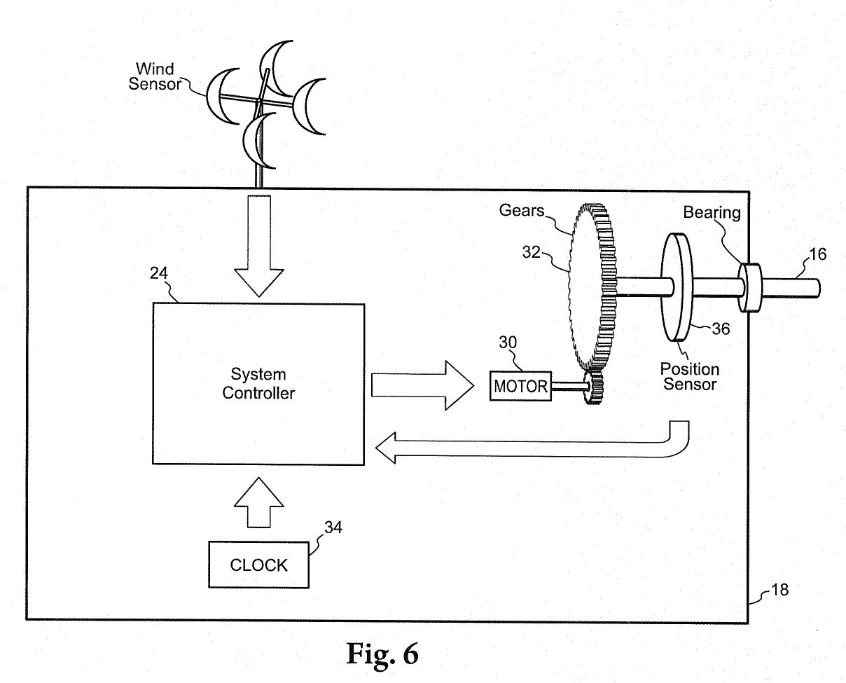

As shown in FIGS. 3 and 6, the tracking solar panel assembly 12 may include a wind velocity sensor 22, which may be used to signal a system controller 24 (See FIG. 6) of the drive mechanism 18 to position the at least one solar panel 14 in the respective tracking solar panel assembly to a substantially flat orientation during times of high wind.

Each tracking solar panel assembly 12 may further comprise a radio frequency (RF) module 26 (FIG. 3) for providing an RF link to at least one central control station (not shown) for the purpose of signaling that one or more of the tracking solar power assemblies is not functioning correctly, to receive a signal instructing the one or more assemblies to shut down and return to the horizontal position (for example, on a cloudy day), or communicate other information using radio frequency transmission as well known to one skilled in the art. In this way, each assembly may report its status, receive instructions, or otherwise communicate other information.

As shown in FIG. 6, the exemplary drive mechanism 18 for each tracking solar panel assembly 12 may comprise a housing (not shown) and a motor assembly (not shown) disposed within the housing. With reference to FIG. 2, the drive mechanism is shown in isolation. The motor assembly comprises a motor 30 and gears 32 mounted in the housing. The motor may be an electric motor appropriately sized for the weight, snow load and wind load of solar panel that it rotates. The motor assembly imparts rotary motion via the gears 32 to the rotatable support structure 16. The motor assembly further comprises the system controller 24 that may be mounted in the housing. A clock 34 and position sensor 36 may be used to provide information to the system controller 24 It is noted that power to the motor assembly can be supplied from the solar panel with a local rechargeable battery to permit operation during cloudy moments- The controller is operable to energize the motor assembly and rotate the respective support structure for orienting the at least one solar panel to track the angle of the sun. In a preferred embodiment, the controller is a standard electric controller, however, it is within the scope of this invention for the controller to be an electrically operated motor or other suitable actuation device. Such systems may be operated under computer control according to the expected solar orientation, or may use a tracking sensor to control the drive mechanism that orients the at least one solar panel toward the sun.

It is understood that the drive mechanism 18 used to effect rotation of the support shaft in accordance with the present invention is well known in the art and that other configurations for the drive mechanism are within the spirit and scope of the invention.

The drive mechanism 18 gradually rotates the respective solar panel(s) throughout the solar day from an east-facing direction in the morning to a west-facing direction in the afternoon as shown by the arrows in each of the figures. The at least one solar panel 14 is subsequently brought back to the east-facing orientation for the next day. The at least one solar panel desirably rotates around a single axis that is generally horizontal. Alternatively, the solar panels may be adapted to rotate around a single axis that is tilted on an angle relative to horizontal that corresponds to the latitude of the location. A tilted single-axis tracking structure generally achieves a performance that is improved relative to horizontal single-axis tracking structures because it places the solar panels on average closer to perpendicular relative to the path of the sun. As each tracking solar panel assembly is independent, the at least one solar panel of each tracking solar panel assembly can be oriented so that it has a fixed tilt to the south in the range of 20-40 degrees and then tracks the sun from east to west. (See FIG. 5) In the prior art, many solar panels are connected together in the north to south direction preventing them from also being tilted in the north-south direction forcing the north-south tilt to be zero degrees. Compared to zero degree fixed tilt in the southern direction, a fixed tilt in the range of 20-40 degrees will improve the yearly energy production by more than 5%.

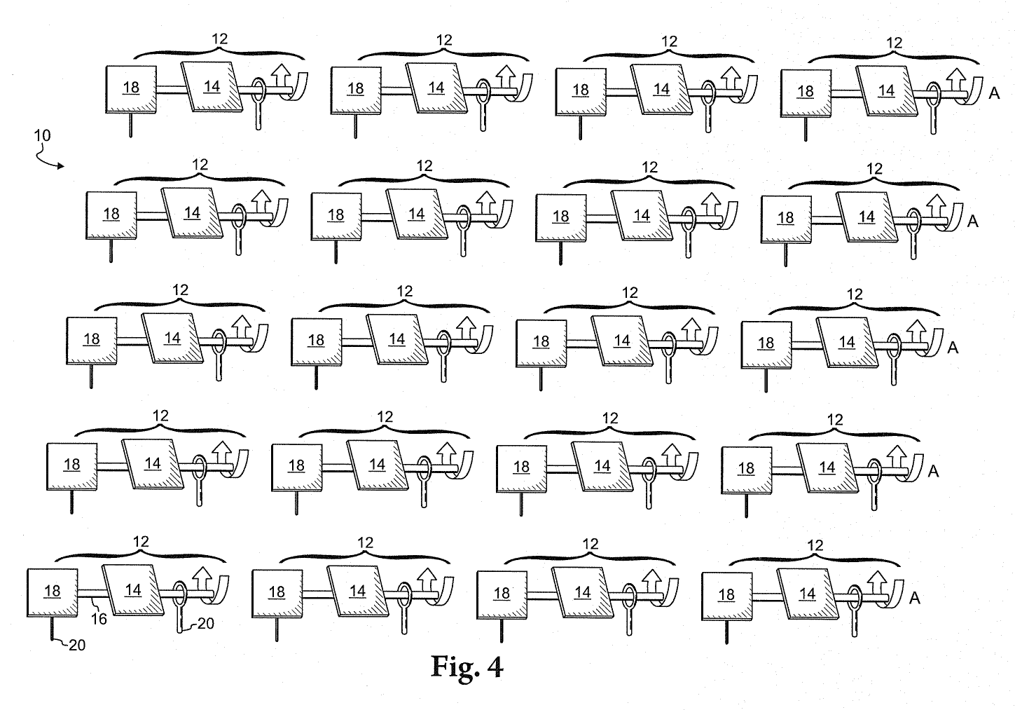

The independent tracking solar panel assemblies 12 may be arranged in rows (designated with the letter “A”) in the array 10. The array includes multiple rows, in the exemplary case shown in FIG. 2, four rows of tracking solar panel assemblies are shown, each assembly having one solar panel. In an exemplary embodiment, the solar panels are about two meters wide and about two meters long. The present invention is not limited to the specific configuration of tracking solar panel assemblies or solar panels presented herein, but may instead be scaled to accommodate other size panels and/or different quantities of rows, assemblies within the row and within the array, and solar panels. In a preferred embodiment, the number of solar panels per assembly may be one or two. The amount of extra capacity or redundancy can be designed to accommodate the likely probability of multiple failures. FIG. 4 shows an exemplary array with one extra redundant row of tracking solar panel assemblies. While substantial benefit may be derived from an orderly arrangement of tracking solar panel assemblies, an “array” as used herein includes disordered arrangements of tracking solar panel assemblies.

Each independent solar panel assembly may be wired directly to a power inverter (not shown) for converting the DC current from one or more assemblies to a desired AC electricity. The tracking solar panel assemblies within the solar collection array may be wired in parallel. Each may be protected with a series diode 28 so that if one shorts, it cannot shunt power from another. Therefore, if one tracking solar panel assembly fails, the power from each of the other tracking solar panel assemblies within the solar collection array continues unaffected to the power inverter.

In a solar farm of moderate size (e.g. 10 MW), there may be tens of thousands of independent tracking solar panel assemblies. Each could be designed for high volume production so that the total cost of the many tracking solar panel assemblies in this invention would be less than the total cost of the few tracking solar collection systems in the prior art.

From the foregoing, it is to be appreciated that the present invention provides reliable power generation with a small amount of redundancy using relatively inexpensive components. As the tracking solar panel assemblies operate independently of each other, a single point of failure only renders a single assembly inoperable. As a single assembly produces only a small fraction of the power of the array, only a small percentage of the power generating capacity is affected by the failure of a single assembly, thereby substantially reducing downtime and minimizing maintenance of the solar collection system. Moreover, as the support structure has ground variation adaptability, each assembly may be supported in uneven ground or on supports that are uneven in height without the need for concrete foundations. This significantly reduces installation costs. The drive mechanism for independently pivoting the solar panels is mechanically straightforward and relatively inexpensive, and the reduction in concrete requirements and the mechanical simplicity of the support structure makes the solar collection array of the present invention competitive with other solar collection systems.

Although a particular embodiment of the invention has been described in detail for purposes of illustration, various modifications may be made without departing from the spirit and scope of the invention. Accordingly, the invention is not to be limited, except as by the appended claims.

We claim:

1. A solar collection array comprising:
a plurality of tracking solar panel assemblies each comprising:
at least one energy conversion module mounted on a single-axis support structure; and
a drive mechanism for rotating the single-axis support structure of the respective tracking solar panel assembly to track the sun, whereby each of the plurality of tracking solar panel assemblies operate independently from the other tracking solar panel assemblies within the solar collection array.

2. The solar collection array of claim 1 wherein the at least one energy conversion module comprises at least one solar panel.

3. The solar collection array of claim 2 wherein the at least one solar panel is held at a fixed angle in the north to south direction.

4. The solar collection array of claim 3, wherein the at least one solar panel tilts in the north to south direction in the range of 20-40 degrees.

5. The solar collection array of claim 2, wherein the drive mechanism comprises a motor assembly driven by a controller to position the at least one solar panel to track the angle of the sun.

6. The solar collection array of claim 5, wherein each of the tracking solar panel assemblies further comprises a wind sensor that instructs the controller to position the respective energy conversion modules horizontally during high winds.

7. The solar collection array of claim 1 wherein the single-axis support structure is supported at two spaced apart points by a pair of support bearings.

8. The solar collection array of claim 7 wherein the single-axis support structure is supported at one point in the north and one point in the south.

9. The solar collection array of claim 1 wherein each of the tracking solar panel assemblies further comprises a radio frequency communications module connected to at least one central control station to report the status of the respective tracking solar panel assembly and receive instructions to provide to the respective controller.

10. The solar collection array of claim 1 wherein the plurality of tracking solar panel assemblies are connected in parallel and each has a series diode that prevents the power from other tracking solar panel assemblies within the solar collection array from flowing back into one or more tracking solar panel assemblies with a lower output voltage or power.

11. The solar collection array of claim 2 wherein the plurality of tracking solar panel assemblies are arranged in multiple parallel rows, wherein each row includes a plurality of the single-axis support structures oriented north-south defining a north-south axis, the at least one solar panel mounted on each of the single-axis support structures.

12. The solar energy collection array of claim 11, wherein said multiple parallel rows includes four or more such rows.

13. The solar collection array of claim 1, wherein the plurality of tracking solar panel assemblies are wired in parallel with each independent solar panel assembly wired directly to a power inverter protected with a series diode.

14. A tracking solar panel assembly comprising:
at least one energy conversion module mounted on a single-axis support structure wherein the single-axis support structure is supported by no more than two spaced apart points; and
a self-contained drive mechanism for rotating the single-axis support structure of the tracking solar panel assembly to orient the at least one energy conversion module to track the angle of the sun.

15. The tracking solar panel assembly of claim 14 further comprising a wind sensor that instructs a controller of the self-contained drive mechanism to position the at least one energy conversion module horizontally during high winds.

16. The tracking solar panel assembly of claim solar collection array of claim 15 further comprising a radio frequency communications module connected to at least one central control station to report the status of the tracking solar panel assembly and to receive instructions.

17. A method of generating electrical power with a solar collection array, comprising the steps of:
providing a plurality of tracking solar panel assemblies, each comprising:
at least one solar panel mounted on a single-axis support structure; and
a drive mechanism for rotating the single-axis support structure of the respective tracking solar panel assembly to track the sun, whereby each of the plurality of tracking solar panel assemblies operate independently from the other tracking solar panel assemblies within the solar collection array; and
arranging the plurality of tracking solar panel assemblies in parallel rows to form a solar collection array; and
wiring the plurality of tracking solar panel assemblies in parallel with each independent solar panel assembly wired directly to a power inverter protected with a series diode.

18. The method of claim 17 wherein the single-axis support structure is supported at two spaced apart points in the north and in the south by a pair of support bearings.

19. The method of claim 17 wherein the at least one solar panel is held at a fixed angle in the north to south direction.

20. The method of claim 17 wherein the at least one solar panel tilts in the north to south direction in the range of 20-40 degrees.
